(19) United States
(12) Patent Application Publication
(10) Pub. No.: US 2026/0302762 A1
(43) Pub. Date: Oct. 1, 2026

(54) DC INVERSION-BASED AC VALVE CONTROL SYSTEM

(71) Applicant: Fujian OralGarden Technology Co., Ltd., Fuzhou (CN)

(72) Inventors: Dun Zheng, Fuzhou (CN); Zehe Yang, Fuzhou (CN)

(73) Assignee: Fujian OralGarden Technology Co., Ltd., Fuzhou (CN)

(21) Appl. No.: 19/455,731

(22) Filed: Jan. 21, 2026

(30) Foreign Application Priority Data
Mar. 28, 2025 (CN) 202520574179.5

(51) Int. Cl. H02H 7/122; H02M 1/00; H02M 1/088; H03K 7/08; F16K 31/06; H02J 7/00; H02J 101/22

(52) U.S. Cl. CPC H02H 7/1227; H02M 1/0006; H02M 1/0009; H02M 1/088; H03K 7/08; F16K 31/0675; H02J 7/855; H02J 2101/22

(57) ABSTRACT

A DC inversion-based AC valve control system includes a high-voltage alternating current (AC) input circuit, a switching power supply circuit, an H-bridge inverter circuit, a short-circuit overcurrent detection circuit, a low-voltage AC output on-off circuit, a microcontroller unit (MCU) control circuit, a step-down voltage stabilizing circuit, and an AC valve; where the high-voltage AC input circuit is connected to an input terminal of the switching power supply circuit, a first output terminal of the switching power supply circuit is connected to an input terminal of the H-bridge inverter circuit, a second output terminal of the switching power supply circuit is connected to an input terminal of the step-down voltage stabilizing circuit, an output terminal of the H-bridge inverter circuit is connected to an input terminal of the short-circuit overcurrent detection circuit, an output terminal of the short-circuit overcurrent detection circuit is connected to the low-voltage AC output on-off circuit.

### TECHNICAL FIELD

The present disclosure relates to the technical field of voltage conversion, and in particular to a DC inversion-based AC valve control system.

### BACKGROUND

An alternating current (AC) valve is a solenoid valve that uses an AC power to control the shut-on/off or direction of fluid flow, and is widely applied in industrial and household equipment. The advantages of the AC valve are as follows: 1. a fast response speed: an engagement time of the AC solenoid valve is generally shorter than that of a direct current (DC) solenoid valve; 2. a simple structure: the AC valve is relatively simple in design, and easy to install and maintain; and 3. a low cost: compared with the DC solenoid valve, the AC solenoid valve has a lower manufacturing cost.

A garden is usually set up in a residential quarter or a courtyard, and flowers and plants are cultivated in the garden. A water pipe for garden irrigation is equipped with the AC valve, and opening and closing of the AC valve determine whether watering is available for flowers and plants. The AC valve for garden irrigation is compact in size and requires a relatively low AC voltage, and typically a 24V AC power, which belongs to a low-voltage AC power. A conventional AC valve control system uses an iron-core transformer to convert AC 100V or AC 220V to AC 24V. The conventional iron-core transformer is selected according to an input voltage. When an AC 100V transformer is connected to an AC 220V power supply, the transformer may burn out; and when an AC 220V transformer is connected to an AC 100V power supply, an output supply voltage may be insufficient, such that the AC valve fails to open properly. A standard civilian voltage in China is AC 220V, while in the United States and Japan, a standard civilian voltage is AC 100V.

An output voltage of the conventional iron-core transformer varies with changes in the input voltage. When the input voltage is low, the output voltage may drop below AC 24V, thereby affecting normal opening of the AC valve. For an input wide-range high-voltage AC power, a plurality of corresponding iron-core transformers need to be prepared. Due to technical limitations, the overall standby power consumption of the system using the iron-core transformer exceeds 2 W. Therefore, to power the AC valve for garden irrigation more stably, there is an urgent need in the technical field for a DC inversion-based AC valve control system.

### SUMMARY

The technical problem to be solved by the present disclosure is to provide a DC inversion-based AC valve control system.

The present disclosure is implemented as follows: A DC inversion-based AC valve control system includes:

a high-voltage AC input circuit, a switching power supply circuit, an H-bridge inverter circuit, a short-circuit overcurrent detection circuit, a low-voltage AC output on-off circuit, a microcontroller unit (MCU) control circuit, a step-down voltage stabilizing circuit, and an AC valve; where

the high-voltage AC input circuit is connected to an input terminal of the switching power supply circuit, a first output terminal of the switching power supply circuit is connected to an input terminal of the H-bridge inverter circuit, a second output terminal of the switching power supply circuit is connected to an input terminal of the step-down voltage stabilizing circuit, an output terminal of the H-bridge inverter circuit is connected to an input terminal of the short-circuit overcurrent detection circuit, an output terminal of the short-circuit overcurrent detection circuit is connected to an input terminal of the low-voltage AC output on-off circuit, an output terminal of the low-voltage AC output on-off circuit is connected to a power terminal of the AC valve, the AC valve is mounted on a water pipe for garden irrigation, an output terminal of the step-down voltage stabilizing circuit is connected to a power terminal of the MCU control circuit, a sinusoidal pulse width modulation (SPWM) signal transmitting terminal of the MCU control circuit is connected to an SPWM signal receiving terminal of the H-bridge inverter circuit, and a feedback signal transmitting terminal of the short-circuit overcurrent detection circuit is connected to a feedback signal receiving terminal of the MCU control circuit.

Further, the system further includes a key panel, where a key signal transmitting terminal of the key panel is connected to a key signal receiving terminal of the MCU control circuit, and an on-off signal transmitting terminal of the MCU control circuit is connected to an on-off signal receiving terminal of the low-voltage AC output on-off circuit.

Further, the system further includes a liquid crystal display (LCD) screen, where a display signal transmitting terminal of the MCU control circuit is connected to a display signal receiving terminal of the LCD screen.

Further, the system further includes a light-emitting diode (LED) indicator light, where a status signal transmitting terminal of the MCU control circuit is connected to a status signal receiving terminal of the LED indicator light.

Further, the high-voltage AC input circuit is connected to an AC power supply ranging from 90V to 240V, the switching power supply circuit outputs a 35V DC power, the H-bridge inverter circuit outputs a 24V AC power, and the step-down voltage stabilizing circuit outputs a 3.3V DC power.

Further, the system further includes a solar battery, where a first output terminal of the solar battery is connected to the input terminal of the H-bridge inverter circuit, and a second output terminal of the solar battery is connected to the input terminal of the step-down voltage stabilizing circuit.

Compared with the prior art, the beneficial effects of the technical solution of the present disclosure are as follows:

First, the switching power supply circuit is used to rectify a wide-range high-voltage AC power into a stable low-voltage DC power; then, the low-voltage DC power is converted into a required stable low-voltage AC power through an SPWM signal from the MCU control circuit in coordination with the H-bridge inverter circuit; and finally, the low-voltage AC power is supplied to the AC valve. The opening and closing states of the AC valve determine whether the water pipe for garden irrigation sprays water externally. Additionally, the step-down voltage stabilizing circuit is used to generate a power required for the MCU and the MCU control circuit. Meanwhile, the short-circuit overcurrent detection circuit is used for real-time monitoring; and when a short-circuit or overcurrent fault occurs, the short-circuit overcurrent detection circuit automatically cuts off the power to prevent further expansion of the fault. The present disclosure eliminates an iron-core transformer, such that standby power consumption is lower, and the AC valve for garden irrigation is powered more stably.

### BRIEF DESCRIPTION OF THE DRAWINGS

The present disclosure will be further described below in conjunction with the drawings and embodiments.

FIG. 1 is a first schematic structural diagram of a DC inversion-based AC valve control system according to the present disclosure.

FIG. 2 is a second schematic structural diagram of a DC inversion-based AC valve control system according to the present disclosure.

Reference numerals in the figures: 1-high-voltage AC input circuit; 2-switching power supply circuit; 3-H-bridge inverter circuit; 4-short-circuit overcurrent detection circuit; 5-low-voltage AC output on-off circuit; 6-MCU control circuit; 7-step-down voltage stabilizing circuit; 8-AC valve; 9-key panel; 10-LCD screen; 11-LED indicator light; and 12-solar battery.

### DETAILED DESCRIPTIONS OF THE EMBODIMENTS

The present disclosure provides a DC inversion-based AC valve control system, and the overall concept of the technical solution thereof is as follows:

A switching power supply circuit is employed to rectify an input wide-range high-voltage AC power of 90V to 240V into a stable 35V low-voltage DC power; then, the 35V low-voltage DC power is converted into a 24V low-voltage AC power through an SPWM signal from an MCU control circuit in coordination with an H-bridge inverter circuit; and the 24V AC power is supplied through a low-voltage AC output on-off circuit to reach an AC valve for garden irrigation. Additionally, a step-down voltage stabilizing circuit reduces the 35V low-voltage DC power to a 3.3V DC power, which serves as a power supply for the MCU and the MCU control circuit. Meanwhile, a short-circuit overcurrent detection circuit is used for real-time monitoring. When an output current from the H-bridge inverter circuit is too high, circuit connection is disconnected, and a feedback signal is sent to the MCU control circuit. The MCU control circuit then stops outputting an SPWM signal to the H-bridge inverter circuit, thereby stopping the output of the low-voltage AC power to the AC valve and cutting off power supply to the AC valve. Due to adoption of digital switching control, the present disclosure effectively reduces standby power consumption, with the overall standby power consumption of the entire system being less than 0.5 W.

To better understand the above technical solution, the above technical solution will be described below in detail in combination with the drawings and the specific embodiments.

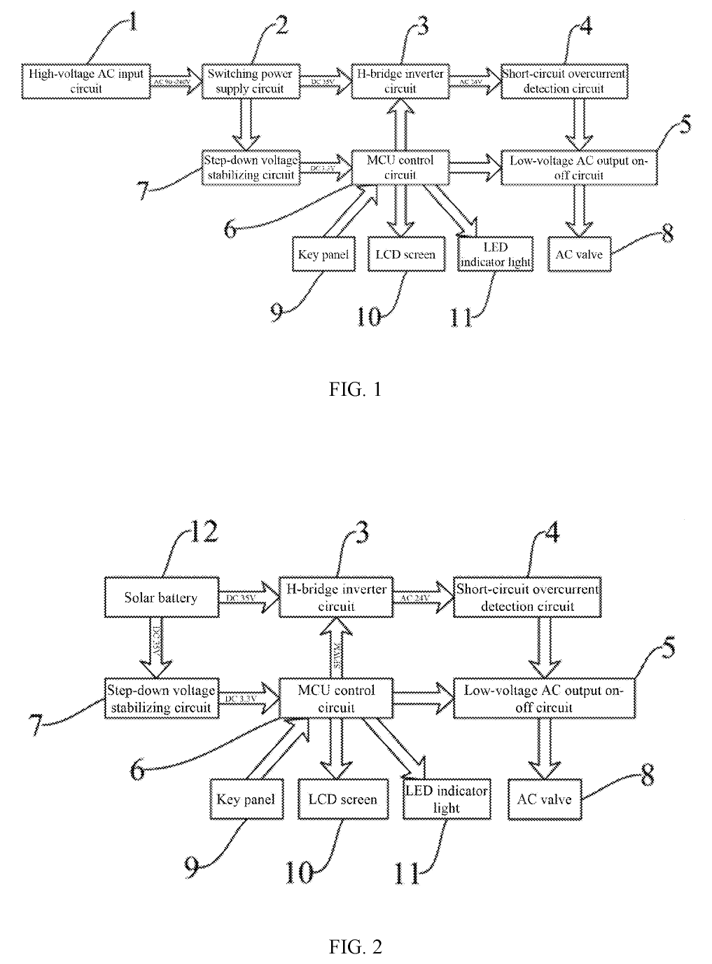

With reference to FIGS. 1 and 2, a preferred embodiment of the present disclosure is provided.

A DC inversion-based AC valve control system includes:

a high-voltage AC input circuit 1, a switching power supply circuit 2, an H-bridge inverter circuit 3, a short-circuit overcurrent detection circuit 4, a low-voltage AC output on-off circuit 5, an MCU control circuit 6, a step-down voltage stabilizing circuit 7, and an AC valve 8; where

the high-voltage AC input circuit 1 is connected to an input terminal of the switching power supply circuit 2, a first output terminal of the switching power supply circuit 2 is connected to an input terminal of the H-bridge inverter circuit 3, a second output terminal of the switching power supply circuit 2 is connected to an input terminal of the step-down voltage stabilizing circuit 7, an output terminal of the H-bridge inverter circuit 3 is connected to an input terminal of the short-circuit overcurrent detection circuit 4, an output terminal of the short-circuit overcurrent detection circuit 4 is connected to an input terminal of the low-voltage AC output on-off circuit 5, an output terminal of the low-voltage AC output on-off circuit 5 is connected to a power terminal of the AC valve 8, the AC valve 8 is mounted on a water pipe for garden irrigation, an output terminal of the step-down voltage stabilizing circuit 7 is connected to a power terminal of the MCU control circuit 6, an SPWM signal transmitting terminal of the MCU control circuit 6 is connected to an SPWM signal receiving terminal of the H-bridge inverter circuit 3, and a feedback signal transmitting terminal of the short-circuit overcurrent detection circuit 4 is connected to a feedback signal receiving terminal of the MCU control circuit 6.

The beneficial effects or advantages of the technical solution of the present disclosure are as follows: First, the switching power supply circuit 2 is used to rectify a wide-range high-voltage AC power into a stable low-voltage DC power; then, the low-voltage DC power is converted into a required stable low-voltage AC power through an SPWM signal from the MCU control circuit 6 in coordination with the H-bridge inverter circuit 3; and finally, the low-voltage AC power is supplied to the AC valve 8. The opening and closing states of the AC valve 8 determine whether the water pipe for garden irrigation sprays water externally. Additionally, the step-down voltage stabilizing circuit 7 is used to generate a power required for the MCU and the MCU control circuit. Meanwhile, the short-circuit overcurrent detection circuit 4 is used for real-time monitoring; and when a short-circuit or overcurrent fault occurs, the short-circuit overcurrent detection circuit 4 automatically cuts off the power to prevent further expansion of the fault. The present disclosure eliminates an iron-core transformer, and the AC valve 8 for garden irrigation is powered more stably.

In this embodiment, the high-voltage AC input circuit 1 may be a plug connected to a mains power supply.

The switching power supply circuit 2 is a power conversion device that converts AC to DC. The circuit converts an input voltage into a pulse signal through switching actions of a switching transistor at a high frequency, and then converts the pulse signal into a DC voltage output through a rectification and filtering circuit. Moreover, this circuit has a feedback control function, and is capable of stabilizing the output voltage by monitoring the output voltage, comparing the output voltage with a reference voltage, and adjusting a pulse width modulation (PWM) duty cycle of the switching circuit. The switching power supply circuit 2 is adaptable to a certain range of input voltages, such as 90V to 240V AC, to accommodate grid voltages in different regions. The switching power supply circuit outputs a 35V DC power.

The H-bridge inverter circuit 3 is of a common inverter topology widely used for DC to AC conversion. The H-bridge inverter circuit is composed of four switching elements (typically metal-oxide-semiconductor field-effect transistors (MOSFET), insulated gate bipolar transistors (IGBT), or other power semiconductor devices) which form an "H"-shaped structure or employs a dedicated H-bridge integrated circuit. By controlling conduction and cutoff states of the four switching elements, a DC input voltage is converted into an AC output voltage. The H-bridge inverter circuit outputs a 24V AC power.

The SPWM signal is a special type of PWM technique, and the core thereof lies in controlling the variation of a pulse width to enable an output signal waveform to approximate a sinusoidal wave. The SPWM signal controls the conduction and cutoff states of the switching elements in the H-bridge inverter circuit.

The short-circuit overcurrent detection circuit 4 is a protective circuit configured to detect presence of a short circuit or overcurrent phenomenon in the circuit, with the purpose of rapidly cutting off the power supply under abnormal circumstances to ensure the safety of the circuit and equipment. The short-circuit overcurrent detection circuit also sends an overcurrent feedback signal to the MCU control circuit, and the MCU control circuit then stops outputting the SPWM signal to the H-bridge inverter circuit. The short-circuit overcurrent detection circuit 4 may also be a current transformer, configured to monitor a current magnitude in real time and provide a feedback to the MCU control circuit which then determines whether the current is excessive.

The low-voltage AC output on-off circuit 5 is configured to transmit a 24V AC power to the AC valve 8. The AC valve 8 for garden irrigation is compact in size and requires a relatively low AC voltage, and typically a 24V AC power, which belongs to a low-voltage AC power.

The step-down voltage stabilizing circuit 7 is configured to convert a 35V DC power outputted by the switching power supply circuit 2 into a 3.3V DC power which is supplied to the MCU control circuit 6.

The core of the MCU control circuit 6 is a microcontroller, which integrates a central processing unit (CPU), a memory, and peripheral functions. The MCU control circuit 6 is an indispensable component in a modern electronic system and is widely applied in various devices, including household appliances, industrial equipment, and automotive electronics.

Further, the system further includes a key panel 9, where a key signal transmitting terminal of the key panel 9 is connected to a key signal receiving terminal of the MCU control circuit 6, and an on-off signal transmitting terminal of the MCU control circuit 6 is connected to an on-off signal receiving terminal of the low-voltage AC output on-off circuit.

An operator sets the MCU control circuit 6 through the key panel 9. During maintenance, the key panel 9 is used to enable the MCU control circuit 6 to send an on-off signal, thereby changing an on-off state of the low-voltage AC output on-off circuit 5 to manually control opening and closing of the AC valve 8. The low-voltage AC output on-off circuit 5 may also be a relay.

Further, the system further includes a liquid crystal display (LCD) screen 10, where a display signal transmitting terminal of the MCU control circuit 6 is connected to a display signal receiving terminal of the LCD screen 10.

The LCD display screen 10 is configured to display relevant settings of the MCU control circuit 6.

Further, the system further includes an LED indicator light 11, where a status signal transmitting terminal of the MCU control circuit 6 is connected to a status signal receiving terminal of the LED indicator light 11.

The LED indicator light 11 is configured to indicate the status of the AC valve 8, such as whether the AC valve is powered or operating.

Further, the system further includes a solar battery 12, where a first output terminal of the solar battery 12 is connected to the input terminal of the H-bridge inverter circuit 3, and a second output terminal of the solar battery 12 is connected to the input terminal of the step-down voltage stabilizing circuit 7.

When a high-voltage AC power socket in a garden loses power or when no high-voltage AC power socket is available, the solar battery 12 is used for power supply. The solar battery 12 outputs a low-voltage DC power, then the low-voltage DC power is converted into a required stable low-voltage AC power through the H-bridge inverter circuit 3, and finally the low-voltage AC power is supplied to the AC valve 8. The low-voltage DC power outputted from the solar battery 12 is also used by the step-down voltage stabilizing circuit 7 to generate a power required for the MCU control circuit.

In this embodiment, the solar battery normally outputs a 12V DC power, the 12V DC power is boosted to a 35V DC power through a voltage booster, and then the 35V DC power is transmitted to the H-bridge inverter circuit and the step-down voltage stabilizing circuit, respectively.

The functions of the present disclosure are described below in detail: The present disclosure employs DC inversion technology to rectify a wide-range AC input voltage of 90V to 240V AC into a stable DC voltage; then, through the MCU control circuit, the SPWM signal, and the H-bridge inverter circuit, the 35V DC voltage is converted into a stable 50 Hz or 60 Hz AC voltage, and a 24V AC power is outputted. Meanwhile, the short-circuit overcurrent detection circuit is used for real-time monitoring; and when a short-circuit or overcurrent fault occurs in the output, the short-circuit overcurrent detection circuit automatically cuts off the power to prevent further expansion of the fault. Due to adoption of digital switching control, the present disclosure effectively reduces standby power consumption, with the overall standby power consumption of the entire system being less than 0.5 W.

The switching power supply circuit converts an AC input voltage into a DC voltage through switching control, and employs isolated conversion to ensure electrical safety of the output terminal. Meanwhile, the switching power supply circuit has an overtemperature protection function to prevent safety problems caused by excessively high operating temperatures of the power supply. The output voltage of the switching power supply circuit is supplied to the H-bridge inverter circuit and the step-down voltage stabilizing circuit, respectively.

The short-circuit overcurrent detection circuit continuously monitors an output current from the H-bridge inverter circuit. When an overcurrent or short-circuit risk is detected, the short-circuit overcurrent detection circuit controls an MOSFET to cut off the AC power outputted to the low-voltage AC output on-off circuit, thereby protecting the AC valve from damage due to a high current. Meanwhile, an overcurrent fault signal is fed back to the MCU control circuit for processing.

The step-down voltage stabilizing circuit converts the 35V DC voltage into a 3.3V DC voltage through a switching step-down or linear step-down method and outputs the 3.3V DC voltage to the MCU control circuit.

The MCU control circuit generates a corresponding SPWM signal to control forward or reverse conduction of the H-bridge inverter circuit, thereby forming a 50 Hz or 60 Hz AC 24V voltage. Meanwhile, the MCU control circuit may control the on or off state of the low-voltage AC output on-off circuit according to a set work schedule. Setting values are inputted through the key panel, and the MCU control circuit displays the inputted setting values and execution status through the LCD display screen. The execution status is indicated through the LED indicator light.

The low-voltage AC output on-off circuit is also configured to filter the 24V AC voltage through inductor-capacitor (LC) filtering to form a pure sinusoidal AC voltage.

The step-down voltage stabilizing circuit is not limited to using the switching step-down or linear step-down method to generate the 3.3V DC voltage.

The H-bridge inverter circuit is not limited to using a discrete device or an integrated drive chip to achieve generation of a forward or reverse switching signal.

Although the specific embodiments of the present disclosure have been described above, those skilled in the art should understand that the specific embodiments described herein are illustrative only and are not intended to limit the scope of the present disclosure. Equivalent modifications and variations made by those skilled in the art in accordance with the spirit of the present disclosure should fall within the scope protected by the claims of the present disclosure.

What is claimed is:

1. A DC inversion-based AC valve control system, comprising:
a high-voltage alternating current (AC) input circuit, a switching power supply circuit, an H-bridge inverter circuit, a short-circuit overcurrent detection circuit, a low-voltage AC output on-off circuit, a microcontroller unit (MCU) control circuit, a step-down voltage stabilizing circuit, and an AC valve; wherein
the high-voltage AC input circuit is connected to an input terminal of the switching power supply circuit, a first output terminal of the switching power supply circuit is connected to an input terminal of the H-bridge inverter circuit, a second output terminal of the switching power supply circuit is connected to an input terminal of the step-down voltage stabilizing circuit, an output terminal of the H-bridge inverter circuit is connected to an input terminal of the short-circuit overcurrent detection circuit, an output terminal of the short-circuit overcurrent detection circuit is connected to an input terminal of the low-voltage AC output on-off circuit, an output terminal of the low-voltage AC output on-off circuit is connected to a power terminal of the AC valve, the AC valve is mounted on a water pipe for garden irrigation, an output terminal of the step-down voltage stabilizing circuit is connected to a power terminal of the MCU control circuit, a sinusoidal pulse width modulation (SPWM) signal transmitting terminal of the MCU control circuit is connected to an SPWM signal receiving terminal of the H-bridge inverter circuit, and a feedback signal transmitting terminal of the short-circuit overcurrent detection circuit is connected to a feedback signal receiving terminal of the MCU control circuit.

2. The DC inversion-based AC valve control system according to claim 1, further comprising a key panel, wherein a key signal transmitting terminal of the key panel is connected to a key signal receiving terminal of the MCU control circuit, and an on-off signal transmitting terminal of the MCU control circuit is connected to an on-off signal receiving terminal of the low-voltage AC output on-off circuit.

3. The DC inversion-based AC valve control system according to claim 2, further comprising a liquid crystal display (LCD) screen, wherein a display signal transmitting terminal of the MCU control circuit is connected to a display signal receiving terminal of the LCD screen.

4. The DC inversion-based AC valve control system according to claim 1, further comprising a light-emitting diode (LED) indicator light, wherein a status signal transmitting terminal of the MCU control circuit is connected to a status signal receiving terminal of the LED indicator light.

5. The DC inversion-based AC valve control system according to claim 1, wherein the high-voltage AC input circuit is connected to an AC power supply ranging from 90V to 240V, the switching power supply circuit outputs a 35V direct current (DC) power, the H-bridge inverter circuit outputs a 24V AC power, and the step-down voltage stabilizing circuit outputs a 3.3V DC power.

6. The DC inversion-based AC valve control system according to claim 1, further comprising a solar battery, wherein a first output terminal of the solar battery is connected to the input terminal of the H-bridge inverter circuit, and a second output terminal of the solar battery is connected to the input terminal of the step-down voltage stabilizing circuit.
